(19) United States
(12) Patent Application Publication
(10) Pub. No.: US 2009/0298683 A1
(43) Pub. Date: Dec. 3, 2009

(54) PRODUCTION OF A MATERIAL COMPRISING A MIXTURE OF NOBLE METAL NANOPARTICLES AND RARE-EARTH OXIDE NANOPARTICLES

(76) Inventors: Marc-Charles Lomello-Tafin, Argonay (FR); Jean-Luc Rousset, Lyon (FR); Jean-Michel Moreau, Annecy (FR); Abdelouahed Ait Chaou, Annecy Le Vieux (FR); Franck Morfin, Loire Sur Rhone (FR)

Correspondence Address: CROWELL & MORING LLP;INTELLECTUAL PROPERTY GROUP, P.O. BOX 14300, WASHINGTON, DC, 20044-4300, US

(21) Appl. No.: 12/097,713

(22) PCT Filed: Dec. 15, 2006
(86) PCT No.: PCT/FR06/02746

§ 371 Date: Nov. 10, 2008

(30) Foreign Application Priority Data
Dec. 16, 2005 (FR) 0512833

(51) Int. Cl. B01J 23/10; C09K 3/00; C04B 35/00; C23C 16/00; B22F 3/02; C23C 8/10

(52) U.S. Cl. 502/303; 252/182.33; 502/302; 502/304; 501/94; 427/248.1; 419/66; 148/284; 75/235; 977/773

(57) ABSTRACT

The invention relates to the production of a material comprising a mixture of noble metal nanoparticles and rare-earth oxide nanoparticles. The process comprises the following successive steps:
a) production of a metal alloy comprising at least one noble metal chosen from the group comprising the elements Ru, Rh, Ir, Ag, Au, Pd, Pt, Ni and Cu and at least one rare earth chosen from the group comprising the elements La, Ce, Pr, Nd, Pm, Sm, Eu, Gd, Tb, Dy, Ho, Er, Tm, Yb, Lu, Y and Sc, said alloy containing a crystalline phase the rare earth content of which is greater than 10 at % and the noble metal content of which is between 25 and 75 at %; and
b) oxidation, in an oxidizing atmosphere, of the metal alloy obtained during step a).

The subject of the invention is also a composite comprising a mixture of noble metal nanoparticles and rare-earth oxide nanoparticles and to the use of such a composite, in particular for catalysis.

The present invention relates to a process for producing a material comprising a mixture of noble metal nanoparticles and rare-earth oxide nanoparticles, to a composite comprising such a mixture and to various uses of this composite.

Numerous fields require the use of materials comprising nanoscale noble metal particles and oxide particles. Such fields include catalysis, optics, magnetism and powder metallurgy.

In particular, noble metals such as gold or palladium are known for their advantageous properties as catalysts. Their catalytic activity is particularly exacerbated when they are in the form of nanoparticles supported on an oxide.

FR 2 779 666 teaches a process for producing materials comprising noble metal nanoparticles and nanoparticles of oxides of a reducing metal, the reducing metal being chosen from column IVB of the Periodic Table of the Elements, namely from titanium, zirconium and hafnium.

However, trials carried out by the inventors have shown that among the numerous noble metal/reducing metal pairs described in that document, only the pair Au/Zr does actually allow a material comprising noble metal nanoparticles and reducing-metal oxide nanoparticles to be obtained. Thus, it seems that the above document cannot reasonably be seen as providing relevant teaching for forming a material comprising noble metal nanoparticles and oxide nanoparticles.

The inventors have now discovered that, by replacing all or part of a non-noble metal (or reducing metal) as indicated in FR 2 779 666 with a rare earth, and by forming a noble metal/rare earth metal alloy having a crystalline phase the composition of which satisfies specified criteria, it is possible to obtain the expected result in terms of structure of material, irrespective of the alloy used.

Thus, according to a first aspect, one subject of the invention is a process for producing a material comprising a mixture of noble metal nanoparticles and rare-earth oxide nanoparticles, comprising the following successive steps:
a) production of a metal alloy comprising at least one noble metal chosen from the group comprising the elements Ru, Rh, Ir, Ag, Au, Pd, Pt, Ni and Cu and at least one rare earth chosen from the group comprising the elements La, Ce, Pr, Nd, Pm, Sm, Eu, Gd, Tb, Dy, Ho, Er, Tm, Yb, Lu, Y and Sc, said alloy containing a crystalline phase the rare earth content of which is greater than 10 at % and the noble metal content of which is between 25 and 75 at %; and
b) oxidation, in an oxidizing atmosphere, of the metal alloy obtained during step a).

Such a process makes it possible to obtain, in a well-controlled manner, a material comprising nanoparticles of different types, namely noble metal nanoparticles and nanoparticles of a rare-earth oxide.

According to a first embodiment, the material obtained is a binary material in which all the noble metal nanoparticles consist of the same noble metal or of an alloy of noble metals, and all the rare-earth oxide nanoparticles contain the same rare earth.

According to a second embodiment, the process according to the invention enables a ternary, quaternary or higher-order material to be obtained. In such a material, the noble metal nanoparticles are formed by a mixture of nanoparticles of different noble metals (for example a mixture of nanoparticles of a noble metal NM₁ and nanoparticles of a noble metal NM₂) and/or by nanoparticles of an alloy of noble metals (NM₁/NM₂ nanoparticles), and the rare-earth oxide nanoparticles are formed by a mixture of nanoparticles of oxides of different rare earths (for example a mixture of nanoparticles of the oxide of a rare earth RE₁ and nanoparticles of the oxide of a rare earth RE₂) and/or by nanoparticles of an alloy of oxides depending on the addition elements comprising at least one rare-earth oxide.

According to one embodiment, the alloy produced during step a) may further include at least one transition metal chosen from the group comprising the elements of column IVB of the Periodic Table of the Elements: Ti, Zr, Hf, from column VB; V, Nb and Ta from column VIB; Cr, Mo and W from column VIIB; Mn, Tc and Re from column IIB; and Zn, Cd and Hg, and the elements Fe, Co and Os.

It is thus possible to obtain a ternary material in which all the noble metal nanoparticles consist of the same noble metal, all the rare-earth oxide nanoparticles contain the same rare earth and all the transition metal oxide nanoparticles contain the same transition metal.

It is also possible to obtain a quaternary or higher-order material. In such a material, the noble metal nanoparticles are formed by a mixture of nanoparticles of different noble metals (for example a mixture of nanoparticles of a noble metal NM₁ and nanoparticles of a noble metal NM₂), the rare-earth oxide nanoparticles are formed by a mixture of nanoparticles of the oxides of different rare earths (for example a mixture of nanoparticles of the oxide of a rare earth RE₁ and nanoparticles of oxides of a rare earth RE₂) or by nanoparticles containing an alloy of several rare earths, and the transition metal oxide nanoparticles contain a mixture of oxides of different transition metals (for example a mixture of nanoparticles of the oxide of a transition metal TM₁ and nanoparticles of the oxide of a transition metal TM₂) or an alloy of several transition metals.

When such hybrid composites are used in catalysis, their catalytic activity may prove to be superior to that of a simple composite containing only a single type of oxide forming a support for the noble metal.

Provision may also be made, in the alloy produced during step a) for the rare earth to be partially replaced with an element of the actinide family chosen from Ac, Th and Pa.

Step a) of the process according to the invention, which consists in producing the metal alloy, may be carried out by various methods known to those skilled in the art. For example, this step may be carried out by melting the pure elements, for example in an arc furnace, or by powder metallurgy or thin films heated to a temperature of 200° C. or higher, or else by mechanical synthesis from the pure elements or alloys, carried out at low temperature and preferably at ambient temperature.

When step a) is carried out at a temperature above 50° C., it is preferably performed in an inert or reducing atmosphere so as to prevent the alloy from oxidizing.

Step b) of the process according to the invention, which consists in oxidizing the alloy produced during step a), is preferably carried out at a temperature below 800° C.

According to one embodiment, step b) is carried out at ambient temperature and may also be carried out in air.

Moreover, between steps a) and b), a heat treatment step may be provided for heating the metal alloy to a temperature between 200° C. and 1000° C. in an inert or reducing atmosphere. Such a step makes it possible to obtain various microstructures of the metal alloy formed during step a).

It is also possible to provide, between steps a) and b), and optionally as a complement to the abovementioned heat treatment step, a step of grinding the metal alloy, intended to increase the rate of oxidation during step b).

Furthermore, the process according to the invention may include, after step b) a step of mechanically grinding or ultrasonically treating the powder obtained, this step being intended to modify (where appropriate, to decrease) the size of the particles obtained.

It is also possible to provide, after step b), a coalescence heat treatment step intended to adjust the size of the particles obtained. This step may also be advantageously combined with step b) of oxidizing the metal alloy, by choosing the oxidation temperature appropriately. The temperature used during this coalescence heat treatment step depends on the constituent elements of the alloy and must be chosen in particular so as not to exceed the melting point of each element.

According to a second aspect, the invention relates to a composite comprising a mixture comprising, on the one hand, nanoparticles of at least one noble metal chosen from the elements Ru, Rh or Ir, Ag, Au, Pd, Pt, Ni and Cu, it being understood that the noble metal nanoparticles may all consist of the same noble metal or else consist of a mixture of nanoparticles of different noble metals (for example a mixture of nanoparticles of a noble metal NM₁ and nanoparticles of a noble metal NM₂) and/or by nanoparticles of an alloy of noble metals (NM₁/NM₂ nanoparticles), and, on the other hand, nanoparticles of at least one oxide of a rare earth, said rare earth being chosen from the elements La, Ce, Pr, Nd, Pm, Sm, Eu, Gd, Tb, Dy, Ho, Er, Tm, Yb, Lu, Y and Sc, it being understood that the nanoparticles of the oxide of a rare earth may all contain the same rare earth, or else they may be formed by a mixture of nanoparticles containing different rare earths (for example a mixture of nanoparticles of the oxide of a rare earth RE₁ and nanoparticles of the oxide of a rare earth RE₂) and/or by nanoparticles of an alloy of oxides of several rare earths and/or an alloy of transition metals depending on the addition elements, said nanoparticles having a particle size of less than 20 nm. This composite has the particular feature of having a high percentage content of noble metal by weight, equal to or greater than 20%.

The composite according to the invention takes the form of a powder containing porous agglomerates, the size of which varies from one micron to a few hundred microns, the agglomerates themselves consisting of an intimate mixture of particles and optionally of noble metal and rare-earth oxide wires, with a size of less than 20 nm.

Such composites have a high specific surface area, of around 60 m²/g, and a high concentration of noble metal, making them particularly advantageous in particular for use in the field of catalysis.

The composite of the invention may further include nanoparticles of at least one oxide of a transition metal, said transition metal being chosen from the group comprising the elements of column IVB of the Periodic Table of the Elements: Ti, Zr, Hf, from column VB; V, Nb and Ta from column VIB; Cr, Mo and W from column VIIB; Mn, Tc and Re from column IIB; and Zn, Cd and Hg, and the elements Fe, Co and Os, it being understood that the transition metal oxide nanoparticles may all contain the same transition metal, or else they may consist of a mixture of nanoparticles of the oxides of different transition metals (for example a mixture of nanoparticles of the oxide of a transition metal TM₁ and nanoparticles of the oxide of a transition metal TM₂) or by nanoparticles containing an alloy of several transition metals and/or rare earths.

The composite according to the invention may also include nanoparticles of at least one oxide of an element from the actinide family, said element being chosen from Ac, Th and Pa.

As indicated above the composites according to the invention may advantageously be used in the field of catalysis, as some of the following examples will show. They may also be used in other fields, such as the manufacture of nonlinear optical instruments or the production of nanoscale oxide powders, for example for the manufacture of sintered ceramics.

The present invention is illustrated below by specific examples of its implementation, to which however it is not limited.

All the metal alloys presented in these examples were synthesized by melting them in an arc furnace in an argon atmosphere.

The materials were characterized in particular by X-ray diffraction (Co—K_{α} and Cu—K_{α}), the diffraction spectra showing intensity I, in arbitrary units, as a function of the diffraction angle 2θ. The particle size was estimated using the Scherrer equation.

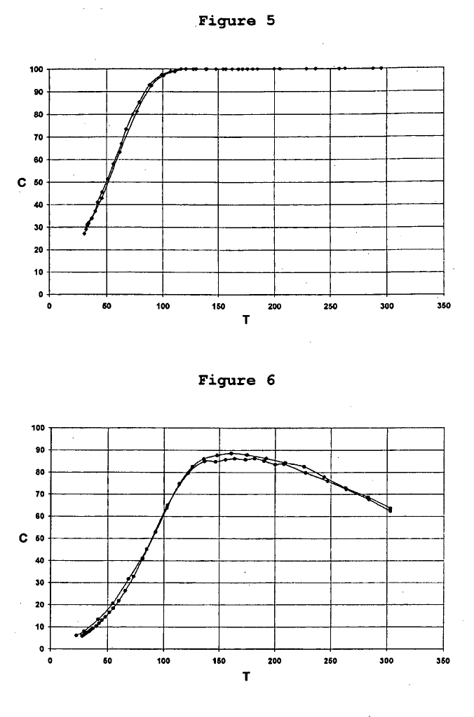

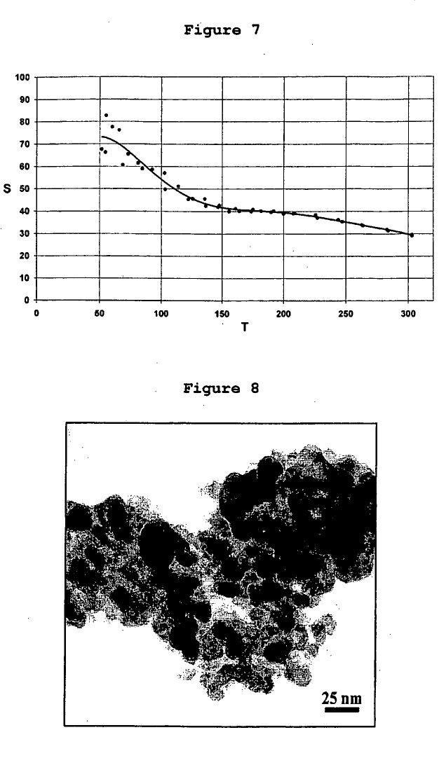

Examples 1 to 13 and 21 to 25 describe the production and characterization of materials obtained according to the process of the invention and the catalytic activity of some of them. The results obtained in simple oxidation of CO are shown in FIGS. 5, 11, 21 and 43c and the results obtained in selective oxidation of CO in the presence of hydrogen are shown in FIGS. 6, 12 and 22, with the degree of conversion of the CO (noted by C as a percentage) being plotted on the y-axis and the temperature T, in degrees Celsius, being plotted on the x-axis. FIGS. 7 and 13 show the degree of selectivity S plotted as a percentage on the y-axis and the temperature T, in degrees Celsius, plotted on the x-axis for the selective oxidation of CO in the presence of hydrogen.

Examples 14 to 20 describe three series of comparative experiments, each series having an example of a binary alloy corresponding to the definition given in document FR 2 779 666 and one or two examples of a ternary alloy obtained by the addition of cerium to the binary alloy, according to the process of the invention.

For these examples, the oxidation was carried out during the thermogravimetric analysis of the alloy carried out in air from 25° C. to 800° C. at a heating rate of 10° C./min.

The figures that show the results of the thermogravimetric analysis are each expressed as three ordinates: the thermal flux F in μV.S/mg; the temperature T in degrees Celsius; and the mass M in mg as a function of the time t in seconds. In each of these figures, the curves denoted by (a), (b) and (c) correspond to the change in thermal flux F, to the change in temperature T and to the change in mass M respectively.

### EXAMPLE 1

### Au/CeO₂ Composite

Production

The equiatomic Ce/Au alloy was synthesized from the elements Au and Ce of purity close to 99%. The synthesis was carried out in a water-cooled crucible so as to prevent contamination at the alloy. The alloy was then coarsely ground, so as to obtain a particle size varying from a few tens of microns to a few hundred microns, and then oxidized by exposure to air with a relative humidity of 60% and at a temperature of 60° C.

Characterization

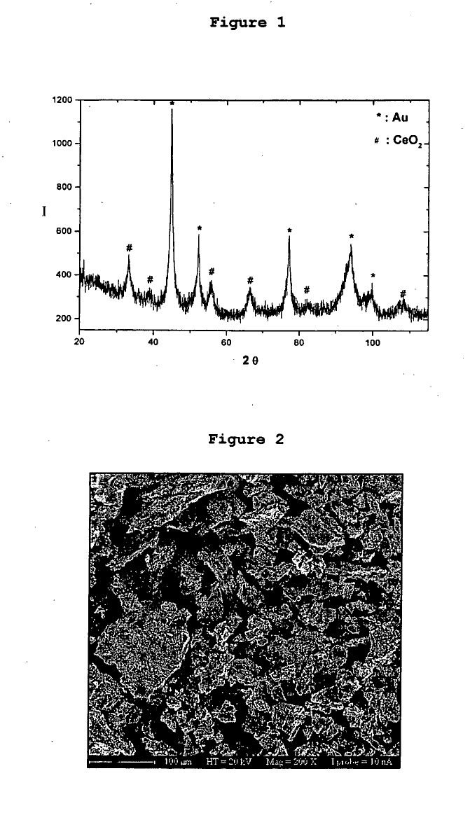

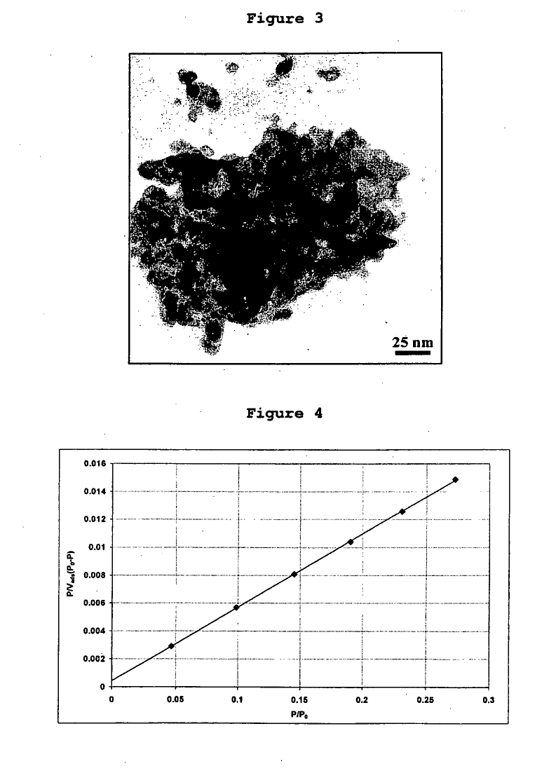

The powder obtained was characterized by X-ray diffraction (FIG. 1), by scanning electron microscopy (FIG. 2), by transmission electron micrography (FIG. 3) and by measuring the specific surface area by the BET method (FIG. 4, which represents the BET adsorption isotherm (P/V_{ads}(P₀−P) as a function of P/P₀), of nitrogen at 77 K).

FIG. 1 shows that the powder obtained is made up of gold particles with a size of about 8 nm and ceria (CeO₂) particles, again of nanoscale size.

The micrograph of FIG. 2 shows that the gold and ceria particles form agglomerates with a size varying from around 10 microns to around 100 microns. These agglomerates are highly porous and consist of a mixture of gold nanoparticles and ceria nanoparticles.

The volume expansion that occurs during the alloy oxidation step results in a division of the agglomerates, thereby explaining the large size distribution, and at the same time leads to the formation of nanoparticles visible by transmission electron micrography. FIG. 3 thus shows a micrograph of the gold nanoparticles of the Au/CeO₂ composite, the oxide having been separated beforehand from the gold by dissolving it in a hydrofluoric acid solution.

The morphology of the powder obtained was confirmed by the high value of the specific surface area. From the curve shown in FIG. 4, it is deduced that the composite has a BET specific surface area of 80 m²/g.

The percentage content of gold by weight in the material was 53.4%.

Catalytic Activity

The catalytic activity of the powder obtained was examined by measuring the degree of conversion of CO as a function of temperature.

FIG. 5 shows the results obtained by making a gas mixture consisting of 2% CO and 2% O₂ in helium pass over 10 mg of powder at a flow rate of 50 ml/min. It appears that the catalytic activity of the composite obtained during oxidation of CO is comparable to that of the best gold-based catalysts produced by conventional chemical methods for the same gold content.

FIG. 6 shows the results of a study of the selective oxidation of CO in the presence of hydrogen, the catalytic properties having been measured for a reactive mixture consisting of 2% CO, 2% O₂ and 48% H₂ in helium, with a flow rate of 50 ml/min. The tests were carried out with 10 mg of powder. The maximum conversion is obtained at 150° C. and the selectivity of this catalyst is of the same order as that of the usual catalysts (FIG. 7).

### EXAMPLE 2

### Au/ZrO₂ (50)/CeO₂ (50) Composite

Production

The ternary alloy Zr_{0.5}Ce_{0.5}Au was synthesized from the elements Au, Zr and Ce of purity close to 99%. The metal alloy obtained was multiphased and composed predominantly of a ZrAu phase and a CeAu phase. The metal alloy, after coarse grinding, was oxidized in air at ambient temperature.

An additional treatment step was carried out on the powder by ultrasound (20 kHz for 10 minutes).

This additional treatment can be used to obtain one particular form of the composite, required for the envisaged application. It may also advantageously be used to control the size of the nanoparticles obtained, in particular for use in liquid-phase catalysis for which the recommended size may be greater than 20 nm (fine chemistry).

Characterization

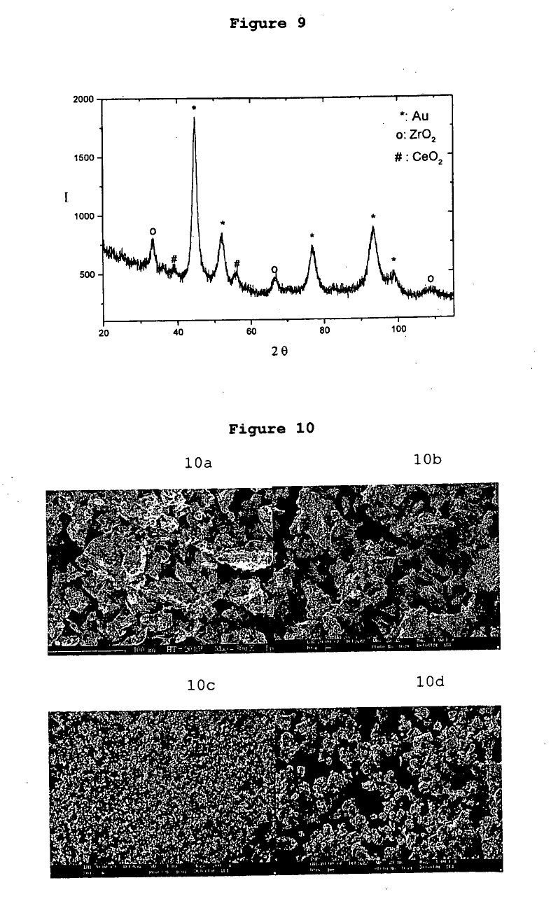

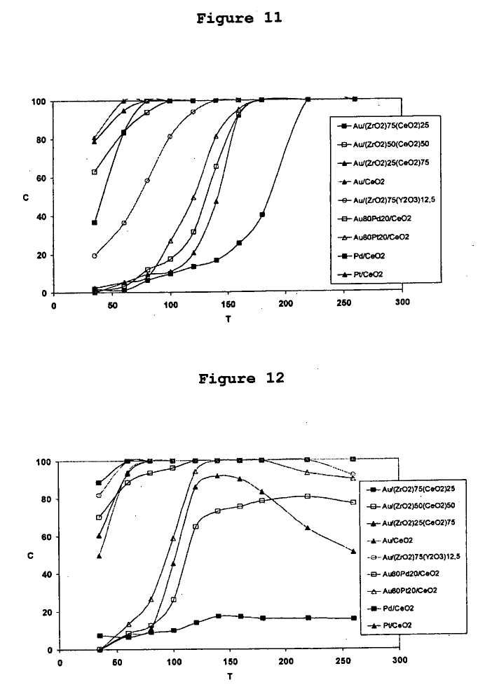

The powder obtained was characterized by transmission electron micrography (FIG. 8), by X-ray diffraction (FIG. 9) and by scanning electron micrography (FIGS. 10a to 10d). FIGS. 10a and 10b are micrographs taken before the ultrasonic treatment, with a respective magnification of 300× and 1000×. FIGS. 10c and 10d are micrographs taken after the ultrasonic treatment with a magnification of 200× and 1000× respectively.

The analysis by transmission electron micrography carried out before the ultrasonic treatment step shows that the metal phase (Au) is very widely dispersed (FIG. 8). The mean size of the base entities is around 5 nm (FIG. 9).

The additional ultrasonic treatment step carried out on the powder allowed the agglomerates consisting of gold nanoparticles and oxide nanoparticles to be fragmented and to be given a uniform size of around 20 μm (FIGS. 10a to 10d).

The morphology of the powder obtained was confirmed by the high value of the specific surface area (63.8 m²/g) measured by the BET method.

The percentage content of gold by weight in the composite was 57.2%.

Catalytic Activity

The catalytic activity was measured for a reaction mixture consisting of 1.72% CO and 3.7% O₂ in nitrogen with a flow rate of 26 ml/min for the simple oxidation and 1.56% CO, 3.3% O₂ and 10% H₂ in nitrogen with a flow rate at 29 ml/min for the selective oxidation of CO in the presence of hydrogen. The tests were carried out with 8 mg of powder mixed with about 800 mg of alumina (Al₂O₃). The alumina was used here as diluent as it does not have a catalytic activity.

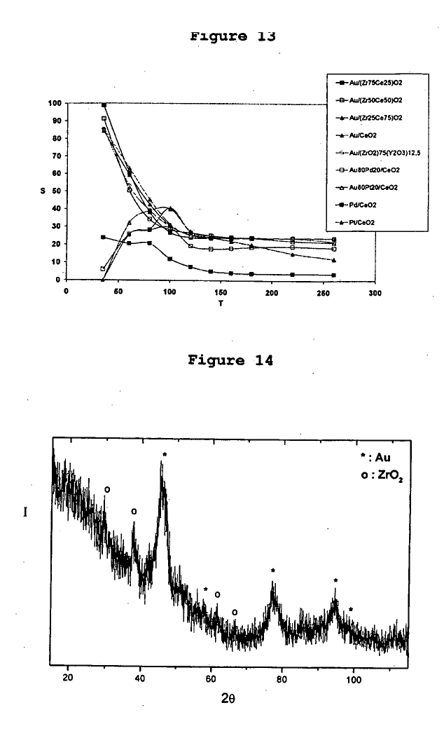

It is apparent that the catalytic activity for CO oxidation (FIG. 11) is comparable to that of the best gold-based catalysts produced by conventional chemical methods for the same gold content, i.e. a degree of conversion of 10% at 100° C. The maximum conversion in preferential oxidation (FIG. 12) is obtained close to 120° C. and the selectivity of this catalyst is 100% at a temperature below 40° C. and remains at the same order of magnitude as that of the standard catalysts (FIG. 13).

### EXAMPLE 3

### Au/ZrO₂(75)/CeO₂(25) Composite

Production

The ternary alloy of Zr_{0.75}Ce_{0.25}Au composition was synthesized from the elements Au, Zr and Ce of purity close to 99%. The metal alloy, after coarse grinding, was oxidized in air at a temperature of 80° C.

Characterization

The characterization of the metal precursor and then of the powder obtained after oxidation was carried out by X-ray diffraction.

The metal alloy was composed predominantly of ZrAu and (Ce,Zr)₉Au₁₁ phases. In the latter phase, Zr partially substitutes for Ce in the Ce₉Au₁₁ phase.

FIG. 14 is the X-ray diffraction spectrum obtained after oxidation. The powder obtained was made up of gold particles with a size close to 6 nm and zirconia ZrO₂ particles, again of nanoscale size. The presence of nanoscale ceria (CeO₂) particles was difficult to identify because of its low concentration.

The specific surface area measured by the BET method was 58.2 m²/g.

The percentage content of gold by weight in the composite was 59.3%.

Catalytic Activity

The catalytic tests were carried out under the same conditions as in Example 2. It is apparent that the catalytic activity of the material obtained during oxidation of CO (FIG. 11) is again comparable to that of the best gold-based catalysts produced by conventional chemical methods for a given gold content, i.e. a degree of conversion of 100% around 75° C. The maximum conversion in preferential oxidation (FIG. 12) is obtained close to 60° C. and the selectivity of this catalyst is 100% at a temperature below 40° C. (FIG. 13).

### EXAMPLE 4

### Au/ZrO₂(25)/CeO₂(75) Composite

Production

The ternary alloy of Zr_{0.25}Ce_{0.75}Au composition was synthesized from the elements Au, Zr and Ce with a purity close to 99%. The metal alloy, after coarse grinding, was oxidized in air at ambient temperature.

Characterization

The characterization of the metal precursor and then of the powder obtained after oxidation was carried out by X-ray diffraction.

The metal alloy is predominantly composed of the CeAu phase (about 80%) and the ZrAu phase.

The powder obtained after oxidation is composed of gold particles with a size close to 7 nm and ceria CeO₂ and zirconia (ZrO₂) particles, again of nanoscale size.

The percentage content of gold by weight in the composite was 55.2%.

Catalytic Activity

The catalytic tests were carried out under the same conditions as in Example 2.

FIG. 11 shows a degree of conversion of 100% around 75° C. in the case of CO oxidation.

In the case of selective CO oxidation in the presence of hydrogen, the maximum conversion is obtained at close to 60° C. (FIG. 12) and the maximum selectivity is obtained at a temperature below 40° C. and remains at the same order as that of the usual catalysts (FIG. 13).

### EXAMPLE 5

### Pd/CeO₂ Composite

Production

The binary alloy of Ce_{0.5}Pd_{0.5} composition was synthesized from the elements Pd and Ce with a purity of close to 99%. The metal alloy, after coarse grinding, was oxidized in air at a temperature of 80° C. and with a relative humidity of 100%.

Characterization

The characterization of the metal precursor and of the powder obtained after oxidation was carried out by X-ray diffraction.

The metal alloy was a single-phase alloy consisting of the CePd phase.

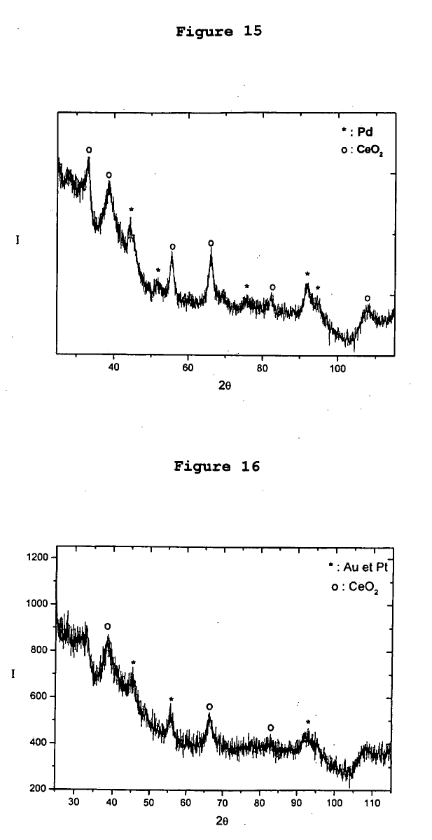

FIG. 15 is the X-ray diffraction spectrum obtained after oxidation, showing that the powder obtained is made up of palladium particles with a size close to 5 nm and ceria (CeO₂) particles again with a nanoscale size (7 to 9 nm).

The percentage content of palladium by weight in the composite was 38.2%.

Catalytic Activity

The catalytic tests were carried out under the same conditions as in Example 2. Although the size of the palladium particles was less than 10 nm, the Pd/CeO₂ composite was active only at high temperature (220° C.) in CO conversion (FIG. 11) and had only a low activity in preferential oxidation in the presence of hydrogen (FIG. 12) with a maximum CO conversion of 17.5%.

### EXAMPLE 6

### Pt/CeO₂ Composite

Production

The binary alloy of Ce_{0.5}Pt_{0.5} composition was synthesized from the elements Pt and Ce of purity close to 99%. The metal alloy, after coarse grinding, was oxidized in air at a temperature of 80° C. and with a relative humidity of 100%.

Characterization

The characterization of the metal precursor and then of the powder obtained after oxidation was carried out by X-ray diffraction.

The metal alloy was a single-phase alloy (CePt phase).

The powder obtained after oxidation was made up of platinum particles with a size of less than 10 nm and ceria (CeO₂) particles, again of nanoscale size.

The percentage content of platinum by weight in the composite was 53.1%.

Catalytic Activity

The catalytic tests were carried out under the same conditions as in Example 2. The complete conversion temperature was 170° C. (FIG. 11) and the CO conversion maximum in preferential oxidation in the presence of hydrogen (92%) was achieved at a temperature of 140° C. (FIG. 12).

### EXAMPLE 7

### Au80,Pt20/CeO₂ Composite

Production

The ternary alloy of Ce_{0.5}Pt_{0.1}Au_{0.4} composition was synthesized from the pure elements Au, Pt and Ce with a purity close to 99%. The metal alloy, after coarse grinding, was oxidized in air at a temperature of 100° C. with a relative humidity of 100%.

Characterization

The characterization of the metal precursor and then of the powder obtained after oxidation was carried out by X-ray diffraction (Co—K_{α}). The metal alloy was predominantly composed of the CeAu phase, the only one detected by X-ray diffraction. Given the high solubility of platinum in gold, it is consistent to find gold substituted with platinum in the CeAu phase, giving rise to the ternary compound Ce(AuPt).

FIG. 16 is the X-ray diffraction spectrum obtained after oxidation, showing that the powder obtained is made up of gold and platinum particles with a size close to 6 nm and ceria (CeO₂) particles, again of nanoscale size.

The percentage content of noble metal by weight in the composite was 53.3%.

Catalytic Activity

The catalytic tests were carried out under the same conditions as in Example 2. The complete conversion temperature was 170° C. (FIG. 11) and 100% conversion of the CO in preferential oxidation in the presence of hydrogen is achieved at a temperature of 140° C. (FIG. 12).

### EXAMPLE 8

### Au80, Pd20/CeO₂ Composite

Production

The ternary alloy of Ce_{0.5}Pd_{0.1}Au_{0.4} composite was synthesized from the elements Au, Pd and Ce with a purity close to 99%. The metal alloy, after coarse grinding, was oxidized in air at a temperature of 100° C. and with a relative humidity of 100%.

Characterization

The characterization of the metal precursor and then of the powder obtained after oxidation was carried out by X-ray diffraction. The metal alloy was composed predominantly of the CeAu phase, which was the only one detected by X-ray diffraction. Given the high solubility of palladium in gold, it is consistent to find gold substituted with palladium in the CeAu phase, giving rise to the Ce(AuPd) ternary compound.

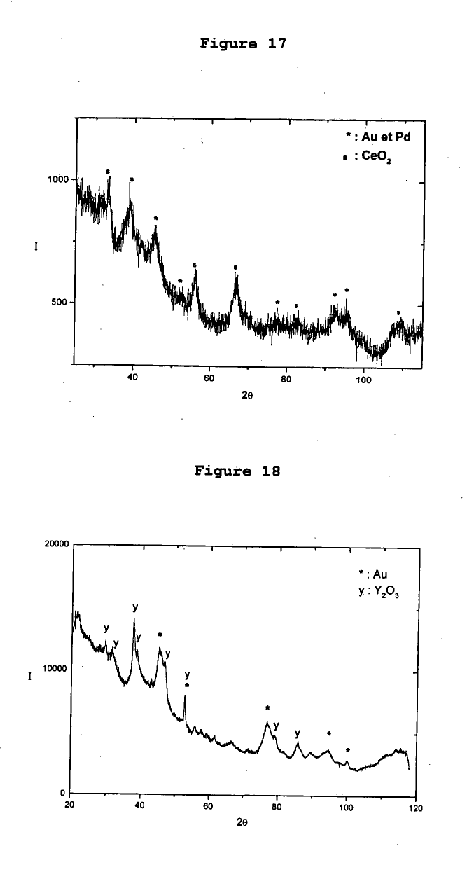

FIG. 17 is the X-ray diffraction spectrum carried out after oxidation, showing that the powder obtained is made up of gold and palladium particles with a size of close to 4 nm and ceria (CeO₂) particles again of nanoscale size.

The percentage content of noble metal by weight in the composite was 51%.

Catalytic Activity

The catalytic tests were carried out under the same conditions as in Example 2. The complete conversion temperature was 170° C. (FIG. 11) and the maximum conversion of CO in preferential oxidation in the presence of hydrogen (80.5%) was achieved at a temperature of 220° C. (FIG. 12). These results are consistent with the low catalytic activity of palladium for these oxidation reactions (Example 5), in agreement with the results in the literature.

### EXAMPLE 9

### Au/Y₂O₃ Composite

Production

The binary alloy of Au_{0.5}Y_{0.5} composition was synthesized from the elements Au and Y with a purity close to 99%. The single-phase alloy (YAu phase) was oxidized in air at ambient temperature without any prior grinding step.

Characterization

The characterization of the metal precursor and then of the powder obtained after oxidation was carried out by X-ray diffraction (FIG. 18). A gold particle size of close to 4 nm was deduced from the width of the diffraction peaks. The yttrium oxide particles were also of nanoscale size.

The percentage content of gold by weight in the material was 63.6%.

### EXAMPLE 10

### Au/ZrO₂/Y₂O₃ Composite

Production

The ternary alloy of Zr_{0.75}Y_{0.25}Au composition was synthesized from the elements Au, Zr and Y with a purity close to 99%. The metal alloy, after coarse grinding, was oxidized in air at ambient temperature.

Characterization

The characterization of the metal precursor and then of the powder obtained after oxidation was carried out by X-ray diffraction. The metal alloy was made up predominantly of the ZrAu and YAu phases. Among impurity phases (<10%) no compound could be identified.

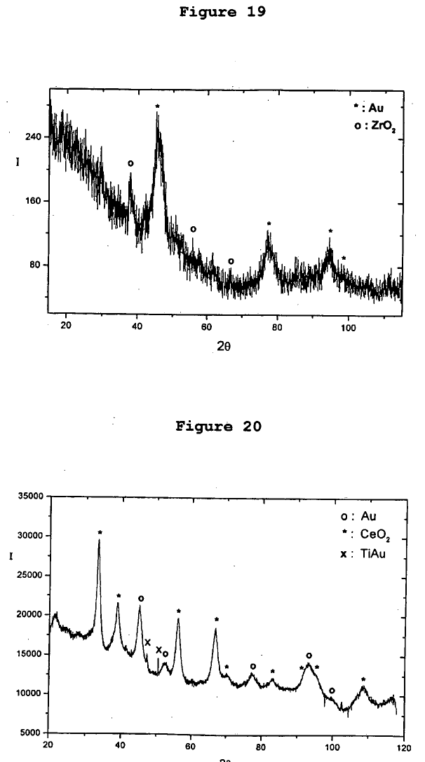

FIG. 19 is the X-ray diffraction spectrum claimed after oxidation, showing that the powder obtained is made up of gold particles with a size close to 4 nm and Y₂O₃ and ZrO₂ oxide particles, again of nanoscale size.

The morphology of the powder obtained was confirmed by the high value of the specific surface area (56.6 m²/g) measured by the BET method.

The percentage content of gold by weight in the composite was 62%.

Catalytic Activity

The catalytic tests were carried out under the same conditions as in Example 2. FIG. 11 shows that the catalytic activity of the material obtained during CO oxidation is comparable to that of the best gold-based catalysts produced by conventional chemical methods for a given gold content, i.e. a degree of conversion of 100% at around 135° C.

In the case of selective CO oxidation in the presence of hydrogen, the maximum conversion is obtained at close to 60° C. (FIG. 12) and the maximum selectivity of this catalyst is obtained at a temperature below 40° C. and remains of the same order of magnitude as that of the usual catalysts (FIG. 13).

### EXAMPLE 11

### Au/TiO₂(15)/CeO₂(65) Composite

Production

The ternary alloy of Ti_{0.15}Ce_{0.65}Au_{0.20} composition was synthesized from the elements Au, Ti and Ce with a purity of close to 99%. The metal alloy, after coarse grinding, was oxidized in air at a temperature of 80° C.

Characterization

The characterization of the metal precursor and then of the powder obtained after oxidation was carried out by X-ray diffraction. The metal alloy was composed predominantly of the Ce₂Au and Ce phases, with the TiAu phase as impurity.

FIG. 20 is the X-ray diffraction spectrum obtained after oxidation, showing that the powder obtained is composed of gold particles with a size close to 6 nm and ceria (CeO₂) particles, again of nanoscale size, and the TiAu phase, the only metal phase that was not oxidized.

The percentage content of gold by weight in the composite was 24.1%.

Catalytic Activity

The catalytic properties were measured for a reaction mixture consisting of 2% CO and 2% O₂ in helium with a flow rate of 50 ml/min in the case of simple oxidation and 2% CO, 2% O₂ and 48% H₂ in helium with a flow rate of 50 ml/min in the case of selective oxidation of CO in the presence of hydrogen. The tests were performed with 6 mg of catalyst.

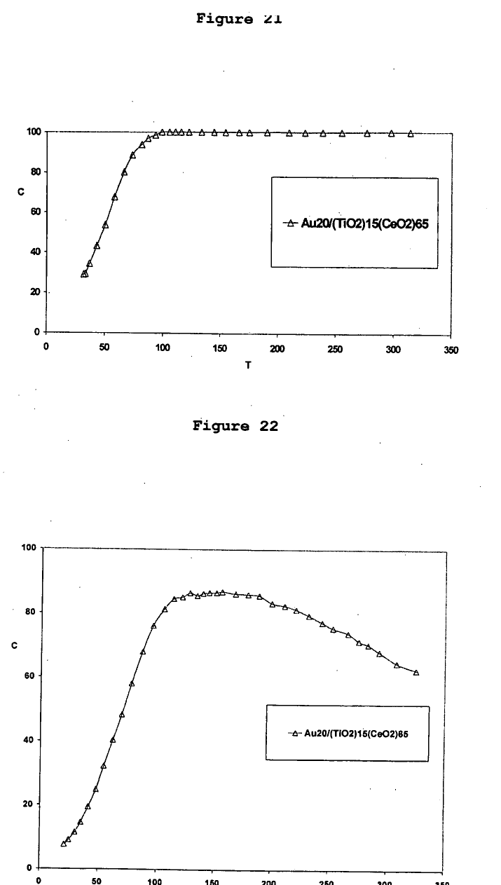

The results obtained in simple oxidation (FIG. 21) and in selective oxidation in the presence of hydrogen (FIG. 22) show an activity comparable to that of the best gold-based catalysts produced by conventional chemical methods for a given gold content, i.e. a degree of conversion of 100% at around 90° C. A maximum conversion in preferential oxidation (90%) lies in a temperature within the 110-175° C. range.

### EXAMPLE 12

### Au/ZrO₂/TiO₂/CeO₂ Composite

Production

The quaternary alloy of the Zr_{0.125}Ti_{0.125}Ce_{0.25}Au_{0.5} composition was synthesized from the elements Au, Zr, Ti and Ce with a purity close to 99%. The metal alloy, after coarse grinding, was oxidized in air at ambient temperature.

Characterization

The characterization of the metal precursor and then of the powder obtained after oxidation was carried out by X-ray diffraction (CuK_{α}).

The alloy was a multi-phase alloy and comprised predominantly the CeAu and Ce₉Au₁₁ phases in which zirconium and titanium may partially substitute for the cerium.

FIG. 23 is the X-ray diffraction spectrum carried out after oxidation, showing that the powder obtained is composed of gold particles with a size close to 7 nm and a mixture of CeO₂, TiO₂ and ZrO₂ oxides, again of nanoscale size.

The percentage content of gold by weight in the composite was 59%.

### EXAMPLE 13

### Au/ZrO₂/TiO₂/Sm₂O₃/CeO₂ Composite

Production

The quinary alloy of Zr_{0.125}Ti_{0.125}Sm_{0.125}Ce_{0.125}Au_{0.50} composition was synthesized from the elements Au, Zr, Ti, Sm and Ce with a purity close to 99%. The metal alloy, after coarse grinding, was oxidized in air at ambient temperature.

Characterization

The characterization of the metal precursor and then of the powder obtained after oxidation was carried out by X-ray diffraction. The metal alloy was a multi-phase alloy and comprised predominantly the (Ce,Sm)Au phase. The other phases present were not identified.

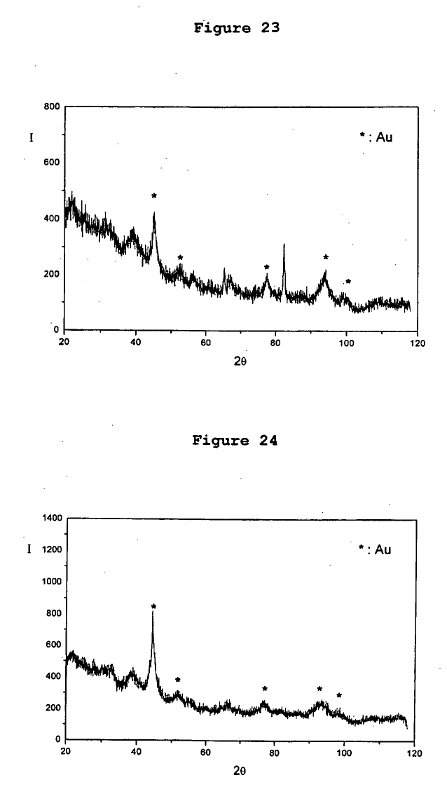

FIG. 24 is the X-ray diffraction spectrum obtained after oxidation, showing that the powder obtained is made up of gold particles with a size close to 5 nm and a mixture of CeO₂, Sm₂O₃, TiO₂ and ZrO₂ oxides again of nanoscale size.

The percentage content of gold by weight in the composite was 58.9%.

### Comparative Example 14

### TiAu Alloy

Production

The single-phase α-TiAu phase was synthesized.

Characterization

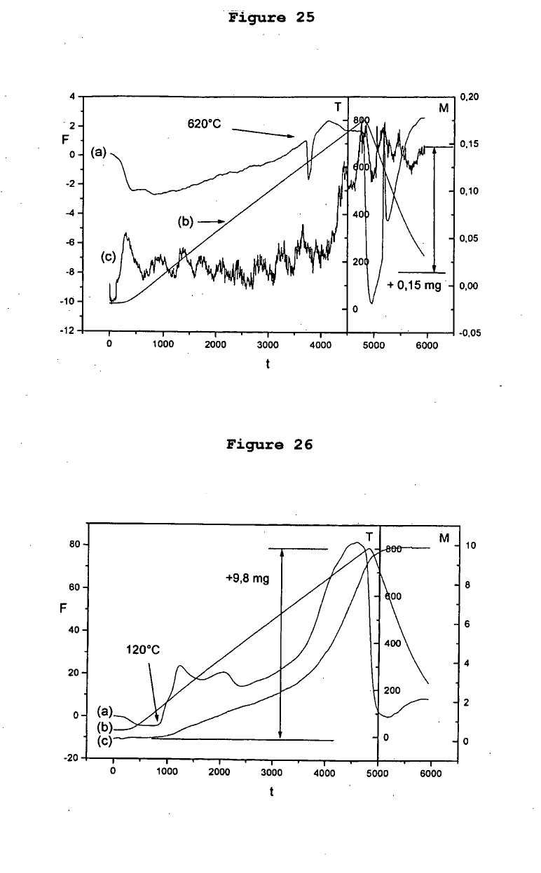

The thermogravimetric analysis of the specimen showed that the TiAu phase was not oxidized (FIG. 25) with a negligible weight uptake of 0.15 mg (i.e. 3%) that occurs close to 700° C. The structural transition of the metallic equiatomic phase, α-TiAu [symbol] β-TiAu, detected at 620° C., was observed. Upon cooling, the reverse transformation, β-TiAu [symbol] α-TiAu, occurs since the TiAu phase is not always oxidized and therefore does not form either titanium oxide nanoparticles or gold nanoparticles.

### EXAMPLE 15

### Au/CeO₂/TiO₂ Composite

Production

The Ce_{0.5}Ti_{0.5}Au alloy was synthesized.

Furthermore, to measure the influence of the choice of oxidation temperature and of the duration of treatment on the size of the nanoparticles, a Ce_{0.5}Ti_{0.5}Au specimen was oxidized at 400° C. in air for 1 h 30.

Characterization

The thermogravimetric analysis (FIG. 26) carried out on the specimen of Ce_{0.5}Ti_{0.5}Au composition showed a weight uptake of 9.8 mg. This weight increase represents 64% of the weight uptake expected for complete oxidation of the specimen according to the reaction:

Ce_{0.5}Ti_{0.5}Au+0₂ [symbol] 0.5CeO₂+0.5TiO₂+Au

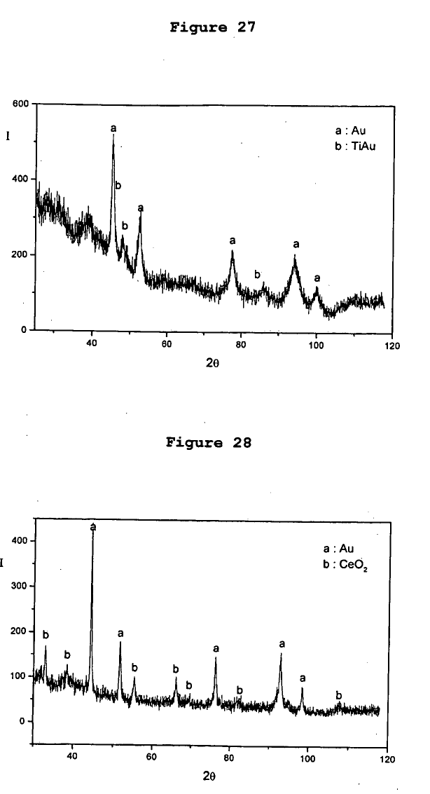

The analysis by X-ray diffraction of the specimen obtained after thermogravimetry showed that the TiAu phase was not oxidized (FIG. 27) and that the size of the gold nanoparticle coherence domains is around 10 nm.

The presence of the TiAu metal phase in the oxidized specimen, in the absence of Ce/Au binary phases (which are very reactive with respect to oxygen) in the starting metal alloy, confirms that only a ternary phase (or several ternary phases) was oxidized.

Furthermore, as illustrated in FIG. 28, the size of the gold particles obtained from the Ce_{0.5}Ti_{0.5}Au specimen oxidized at 400° C. is around 30 nm after treatment for 1 h 30. The choice of oxidization temperature and of the duration of the treatment therefore allows the size of the gold particle coherence domains to be modified and thus in fine, the catalytic properties of the nanocomposite to be controlled.

The percentage content of gold by weight in the composite was 61%.

### Comparative Example 16

### TiPd Alloy

Production

The single-phase α-TiPd phase was synthesized.

Characterization

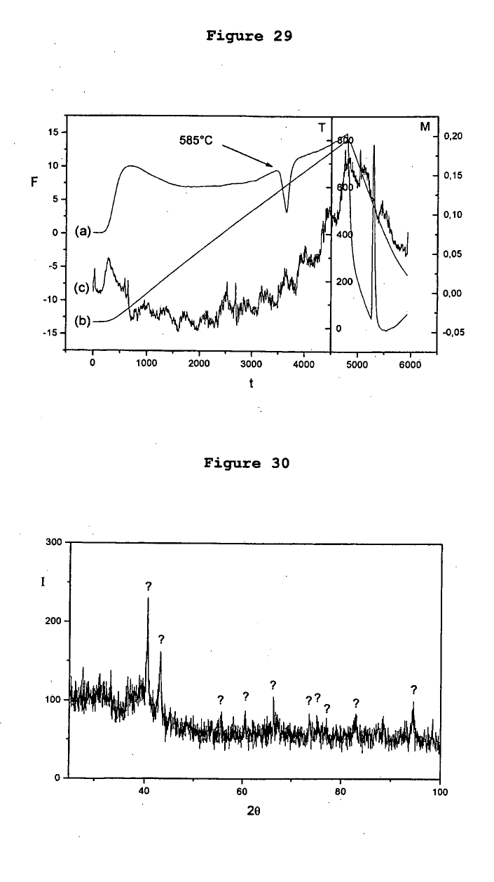

The thermogravimetric analysis (FIG. 29) shows that the TiPd phase was not oxidized, the weight uptake being negligible (0.05 mg, i.e. 0.09%). Only the structural transition of the metallic equiatomic phase α-TiPd [symbol] β-TiPd, detected at 585° C., was observed. During cooling, the reverse transformation, β-TiPd [symbol] α-TiPd, takes place since the TiPd phase is not always oxidized.

### EXAMPLE 17

### Pd/CeO₂/TiO₂ Composite

Production The Ce_{0.5}Ti_{0.5}Pd alloy was synthesized.

An additional heat treatment step was carried out so as to coalesce the palladium particles of the specimen, by subjecting the specimen to a temperature of 1000° C. for 15 days.

Characterization

The X-ray diffraction analysis of the as-melted specimen exhibited diffraction peaks (intensity >20%) belonging to no binary phase, nor to any pure element nor to any of the two oxides CeO₂ and TiO₂ (FIG. 30). As a result, one or more ternary intermetallic compounds were predominantly synthesized.

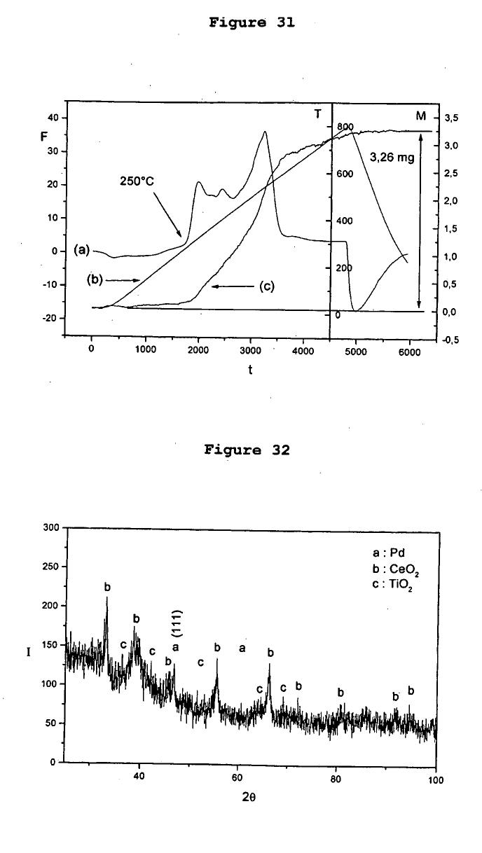

The thermogravimetric analysis (FIG. 31) shows a high reactivity of the specimen above 250° C., leading to a weight uptake of 3.26 mg, which represents 82% of the weight uptake expected for complete oxidation of the specimen leading to the reaction:

Ce_{0.5}Ti_{0.5}Pd+O₂ [symbol] 0.5CeO₂+0.5TiO₂+Pd.

The X-ray diffraction analysis (FIG. 32) of the specimen after thermogravimetry showed the formation of palladium. Palladium particles and/or cross sections of filamentary palladium agglomerates were of subnanoscale size.

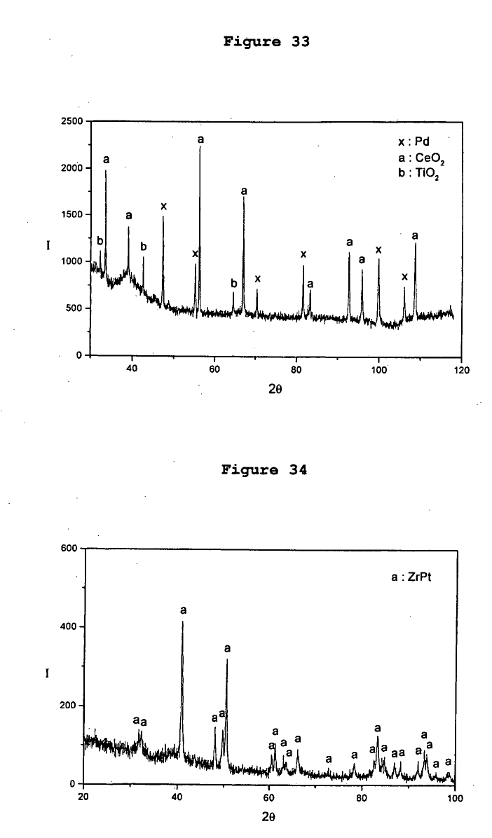

The additional heat treatment carried out on this same alloy demonstrated the presence of pure palladium, with a size of 60 nm, as illustrated in FIG. 33. Specifically, the coalescence of the palladium particles (or wires), initially of subnanoscale size, enables the size of the coalescence domains to be increased.

Thus, since the palladium particles are of subnanoscale size, it is possible to choose, in the case of a palladium-based nanocomposite, the size of the nanoparticles within a very extended range: from subnanometer to several tens of nanometers. By studying the growth rate of the palladium particles it was possible to define the optimum parameters for obtaining the desired nanocomposite.

The percentage content of palladium by weight in the composite was 45.8%.

### Comparative Example 18

### ZrPt Alloy

Production

The Zr_{0.5}Pt_{0.5} alloy was synthesized.

Characterization

FIG. 34, which represents the X-ray diffraction pattern for the metallic Zr_{0.5}Pt_{0.5} specimen, shows that the ZrPt equiatomic compound of orthorhombic CrB crystal structure (Cmcm space group) was formed to 100%; the alloy was therefore a single-phase alloy in agreement with the data from the phase diagram of the Zr—Pt binary system in the literature.

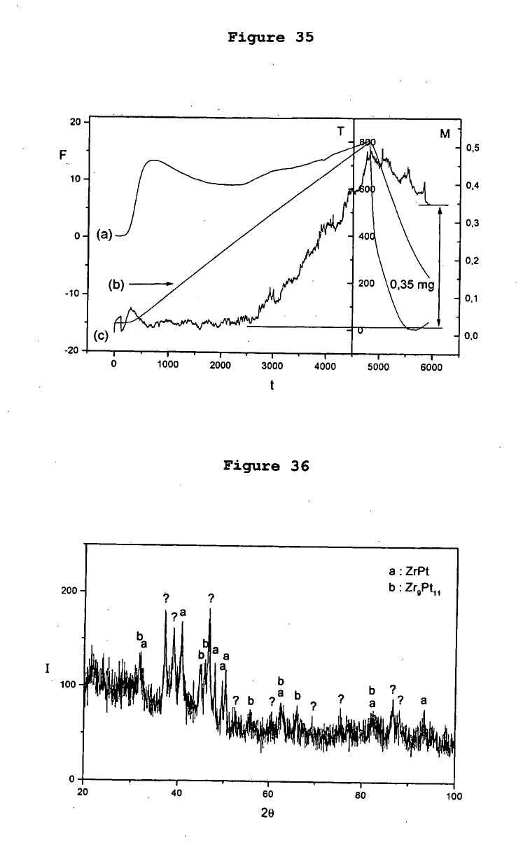

The thermogravimetric analysis (FIG. 35) of the Zr_{0.5}Pt_{0.5} specimen showed that the ZrPt phase was not oxidized in air up to 800° C. with a negligible weight uptake (0.35 mg, i.e. 0.7%).

### EXAMPLE 19

### Composite 1 of the Pt/CeO₂/ZrO₂ Type

Production

The Zr_{0.5}Ce_{0.5}Pt alloy was synthesized.

Characterization

The X-ray diffraction pattern for the Zr_{0.5}Ce_{0.5}Pt specimen before oxidation shows that the metal alloy is a multiphase alloy. Only two binary phases listed in the literature were identified, namely ZrPt and Zr₉Pt₁₁ (FIG. 36). However, the metallographic analysis shows the presence of a predominant ternary phase (FIG. 37). In this image, the phase contrast was revealed by chemical (HNO₃—HCl-ethanol) etching. The large light grains come from the primary crystallization of the ternary phase, while the dark grains come from the secondary crystallization of ZrPt and Zr₉Pt₁₁.

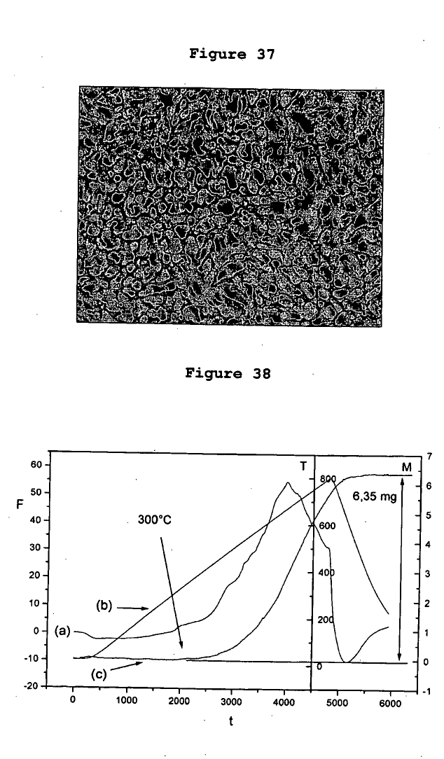

The thermogravimetric analysis of the Zr_{0.5}Ce_{0.5}Pt alloy (FIG. 38) shows that the oxidation of the specimen starts at around 250° C. and results in a total weight uptake of 6.35 mg, which represents 90% of the weight uptake expected for complete oxidation of the specimen according to the reaction:

Zr_{0.5}Ce_{0.5}Pt+O₂ [symbol] 0.5CeO₂+0.5 ZrO₂+Pt.

Owing to the low oxygen affinity of the Zr/Pt binary phases and the fact that the percentage degree of conversion (90%) of the metal alloy is close to the proportion of ternary phase present in the specimen, it therefore appears that the presence of a cerium-based ternary intermetallic compound allowed the Zr_{0.5}Ce_{0.5}Pt alloy to be oxidized at a temperature close to 250° C.

The thermogravimetric analysis was continued up to 800° C. The rate of oxidation increased, leading to 90% conversion in 1 h 30. This same degree of oxidation may also be achieved after several hours at the oxidation start temperature (250° C.).

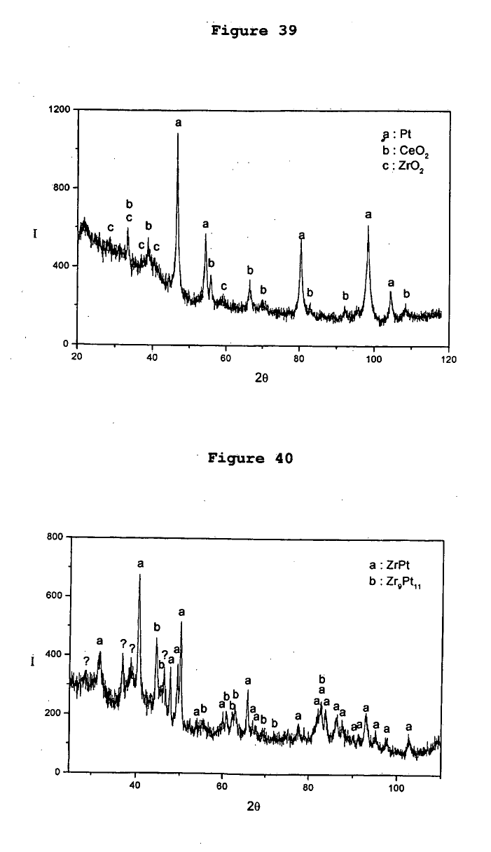

The X-ray diffraction pattern for the specimen after thermogravimetry (FIG. 39) confirms the formation of the Pt/CeO₂/ZrO₂ composite containing platinum nanoparticles and filamentary agglomerates, the size of the coherence domains of which (size of the particles or cross section of the wires) is 20 nm.

The percentage platinum content by weight in the composite was 56.9%.

### EXAMPLE 20

### Composite 2 of the Pt/CeO₂/ZrO₂ Type

Production

A Zr_{0.75}Ce_{0.25}Pt alloy having a proportion of ternary phase less than that of the previous alloy Zr_{0.5}Ce_{0.5}Pt, was synthesized.

Characterization

The X-ray diffraction analysis of the specimen before oxidation showed that the alloy was a three-phase alloy and composed of a ternary phase and ZrPt and Zr₉Pt₁₁ phases (FIG. 40).

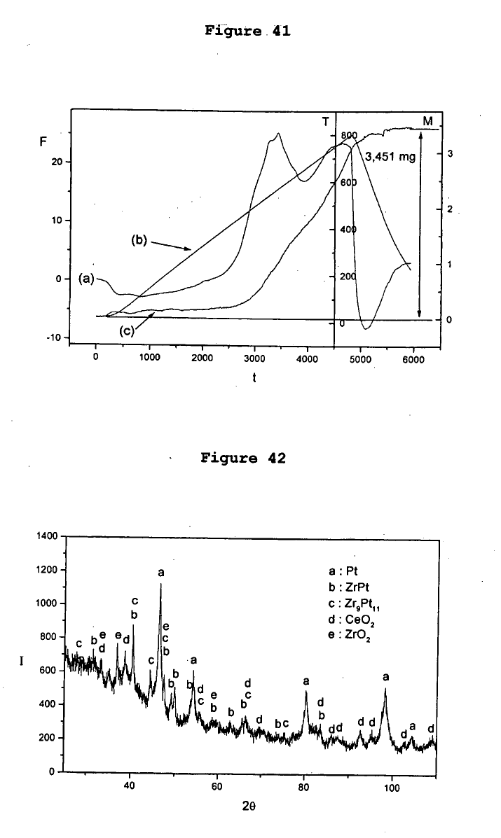

The thermogravimetric analysis of the as-melted specimen (FIG. 41) showed that the alloy oxidized at around 300° C. and resulted in a weight uptake of 3.451 mg, representing 60% of the weight uptake expected for complete oxidation of the specimen according to the reaction:

Zr_{0.75}Ce_{0.25}Pt+O₂ [symbol] 0.75 ZrO₂+0.25 CeO₂+Pt.

The X-ray diffraction analysis of the oxidized specimen resulting from the thermogravimetric analysis showed the presence of pure platinum and of CeO₂ and ZrO₂ oxides, thereby indicating the transformation of a phase containing Zr, Ce and Pt, and therefore a ternary phase. The analysis also showed that the presence of the ZrPt and Zr₉Pt₁₁ binary phases were not oxidized (FIG. 42). This confirms the formation of the Pt/CeO₂/ZrO₂ composite containing platinum nanoparticles, the coherence domain size of which is close to 17 nm, of the same order of magnitude as that (20 nm) of the platinum estimated in the case of the Zr_{0.5}Ce_{0.5}Pt specimen.

The percentage content of platinum by weight in the composite was 59%.

Thus, Examples 14 to 20 show that the process described in document FR 2 779 666 does not lead to the expected results for TiAu, TiPd and ZrPt binary compounds. It is demonstrated that the presence in these metal alloys of a ternary phase containing a rare earth, in this case cerium, makes it possible to form a composite comprising noble metal nanoparticles and oxide nanoparticles.

### EXAMPLE 21

### Composite 1 of Au/PrOₓ Type

Production

The Pr₉Au₁₁ alloy was synthesized from the elements Au and Pr with purity close to 99%. The synthesis was carried out in an inert atmosphere in a water-cooled crucible so as to prevent the alloy from being contaminated. The alloy was then coarsely ground, so as to obtain a particle size varying from a few tens of microns to a few hundred microns, and then oxidized by exposure to air with 60% relative humidity, at a temperature of 50° C.

Characterization

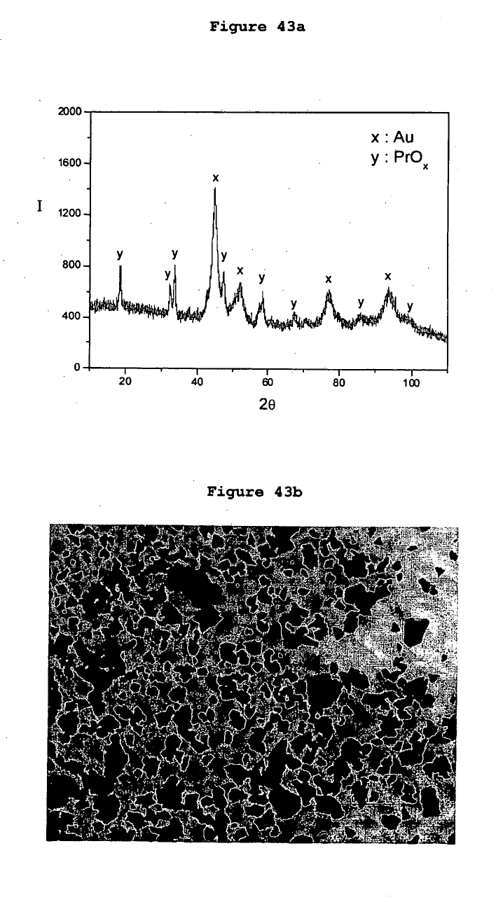

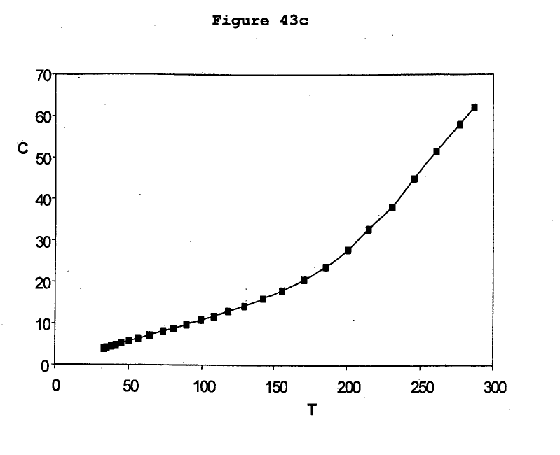

The precursor metal alloy (Pr₉Au₁₁) was characterized by X-ray diffraction. The alloy was composed predominantly (>90%) of the Pr₃Au₄ phase of hexagonal structure (Pu₃Pd₄ type). The powder obtained after oxidation was characterized by X-ray diffraction (FIG. 43a).

FIG. 43a shows that the powder obtained is composed of gold particles with a size close to 8 nm and praseodymium oxide (mixture of PrO₂ and Pr₂O₃) particles, the coherence domains of which (estimated by the Scherrer law) are of nanoscale size close to 40 nm.

The micrograph of FIG. 43 shows that the gold and praseodymium oxide particles form agglomerates, the size of which varies from around 10 microns to around 100 microns. These agglomerates are highly porous and consist of a mixture of gold nanoparticles and praseodymium oxide nanoparticles.

The percentage content of gold by weight in the composite was 58.2%.

Catalytic Activity

The catalytic activity of the powder was obtained by measuring the degree of CO conversion as a function of temperature.

FIG. 43c shows the results obtained in CO conversion as a function of temperature for 10.7 mg of Au/(PrO₂—Pr₂O₃), i.e. 6.2 mg of gold. The experimental conditions were the following: 2% CO, 2% O₂ in He, flow rate 50 ml/min and atmospheric pressure. It should be noted that the catalytic activity depends on the size of the (noble metal and/or oxide) particles, but also on the type of support. In this example, the catalytic activity of the composite obtained during CO oxidation increased with temperature, before reaching values comparable with those observed in the case of gold-based catalysts produced by conventional chemical methods for a given gold content.

### EXAMPLE 22

### Composite 2 of Au/PrOₓ Type

Production

The Pr₃Au₄ alloy was synthesized from the elements Au and Pr with a purity of 99%. The synthesis was carried out in an inert atmosphere in a water-cooled crucible so as to prevent the alloy from being contaminated. The alloy was then coarsely ground, so as to obtain a particle size varying from a few tens of microns to a few hundred microns, and then oxidized by exposure to air with 60% relative humidity, at a temperature of 50° C.

Characterization

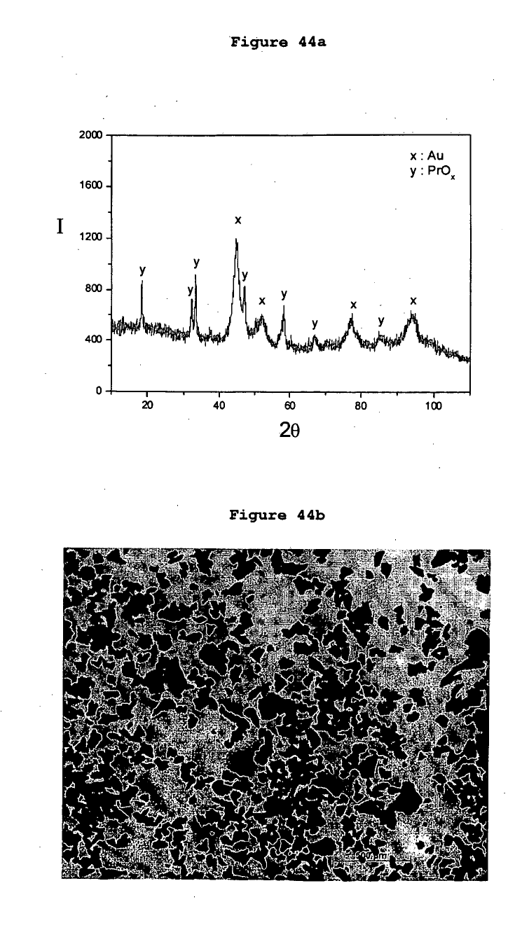

The precursor metal alloy (Pr₃Au₄) was characterized by X-ray diffraction. The alloy was composed only of the Pr₃Au₄ phase of hexagonal structure (Pu₃Pd₄ type). The powder, obtained after oxidation, was characterized by X-ray diffraction (FIG. 44a).

FIG. 44a shows that the powder obtained was composed of gold particles with a size close to 8 nm and praseodymium oxide (a mixture of predominantly PrO₂ and of Pr₂O₃) particles, the size of the coherence domains of which (estimated by the Scherrer law) was close to 40 nm.

The micrograph of FIG. 44b shows that the gold and praseodymium oxide particles form agglomerates of size varying from around 10 microns to around 100 microns. These agglomerates are highly porous and consist of a mixture of gold nanoparticles and PrOₓ nanoparticles.

The percentage content of gold by weight in the composite was 60.3%.

### EXAMPLE 23

### Au/Sm₂O₃ Composite

Production

The Sm₃Au₄ alloy was synthesized from the elements Au and Sm with a purity close to 99%. The synthesis was carried out in an inert atmosphere by melting in an arc furnace in a water-cooled crucible so as to prevent the alloy from being contaminated. The alloy was then coarsely ground, so as to obtain a particle size varying from a few tens of microns to a few hundred microns, and then oxidized by exposure to air with 60% relative humidity, at a temperature of 50° C.

Characterization

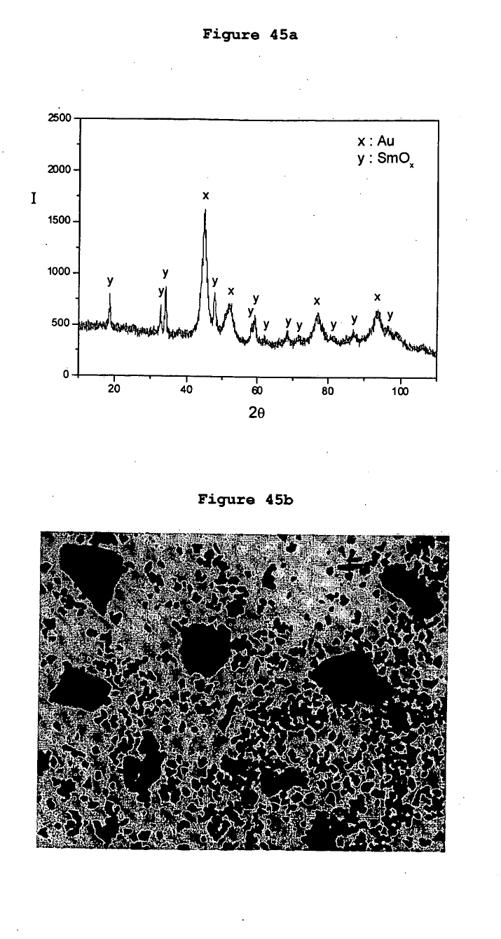

The precursor metal alloy (Sm₃Au₄) was characterized by X-ray diffraction. The alloy was composed only of the Sm₃Au₄ phase of hexagonal structure (Pu₃Pd₄ type). The powder, obtained after oxidation, was characterized by X-ray diffraction (FIG. 45a).

FIG. 45a shows that the powder obtained was composed of gold particles, the size of the coherence domains of which (estimated by the Scherrer law) varied from 5 to 12 nm approximately, depending on the various crystal orientations, and Sm₂O₃ particles, the size of the coherence domains of which was less than 50 nm.

The micrograph of FIG. 45b shows that the gold and samarium oxide particles form agglomerates with a size varying from around 10 microns to around 100 microns. These agglomerates are highly porous and consist of a mixture of gold nanoparticles and Sm₂O₃ nanoparticles.

The percentage content of gold by weight in the composite was 60.1%.

### EXAMPLE 24

### Pt/PrOₓ Composite

Production

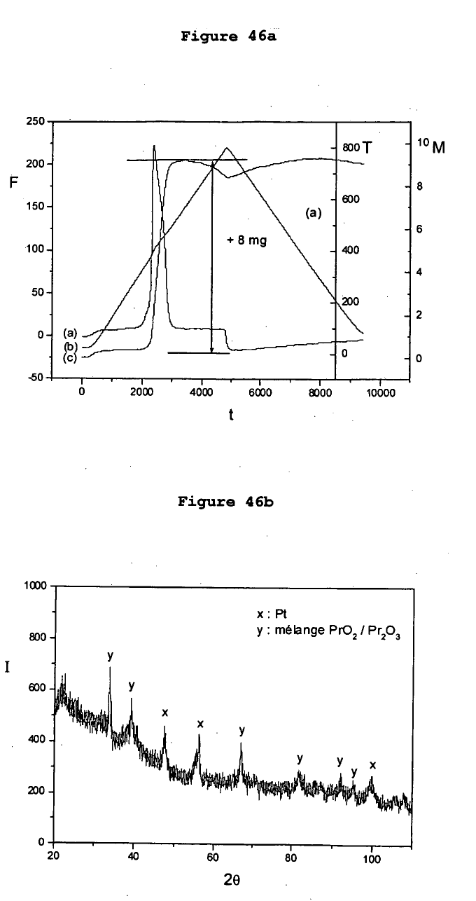

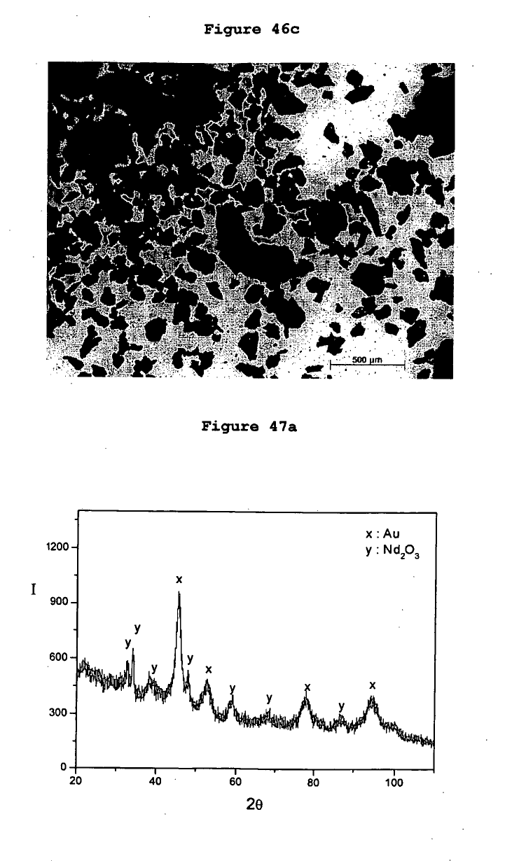

The Pr₃Pt₄ alloy was synthesized from the elements Pt and Pr with a purity close to 99%. The synthesis was carried out in an inert atmosphere in a water-cooled crucible so as to prevent the alloy from being contaminated. The alloy was then coarsely ground, so as to obtain a particle size varying from a few tens of microns to several hundred microns, then heated to 800° C. from ambient temperature at a rate of 10° C./min in air, and then cooled down to ambient temperature at 30° C./min (FIG. 46a).

Characterization

The precursor metal alloy (Pr₃Pt₄) was characterized by X-ray diffraction. The peaks of the predominant phase (>90%) were indexed on the hexagonal structure (Pu₃Pd₄ type).

The thermogravimetric analysis showed that the rate of oxidation of the metal alloy increased at around 300° C. and reached its maximum at about 480° C. (FIG. 46a).

The powder, obtained after oxidation carried out by thermogravimetry, was characterized by X-ray diffraction (FIG. 46b). FIG. 46b shows that the powder obtained was made up of platinum particles with a size close to 16 nm and praseodymium oxide particles (mixture of PrO₂ and Pr₂O₃).

The optical micrograph (FIG. 46c) shows that the platinum and praseodymium oxide particles form agglomerates of very disperse size, ranging from one micron to several hundred microns. These agglomerates are highly porous and consist of a mixture of platinum nanoparticles and praseodymium oxide nanoparticles.

The percentage platinum content by weight in the composite was 61.2%.

### EXAMPLE 25

### Au/Nd₂O₃ Composite

Production

The Nd₃Au₄ alloy was synthesized from the elements Au and Nd with a purity close to 99%. The synthesis was carried out in an inert atmosphere in a water-cooled crucible so as to prevent the alloy from being contaminated. The alloy was then coarsely ground, so as to obtain a particle size varying from a few tens of microns to a few hundred microns, and then oxidized in air at 50° C.

Characterization

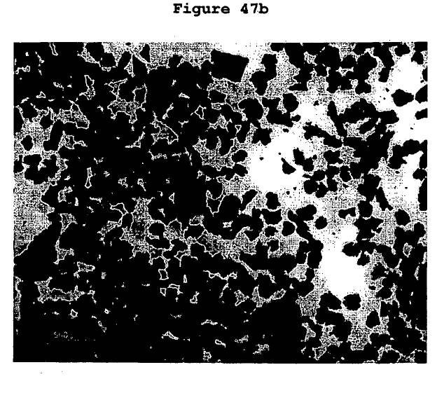

The powder, obtained after oxidation carried out by thermogravimetry, was characterized by X-ray diffraction (FIG. 47a). FIG. 47a shows that the powder obtained was made up of gold particles with a size close to 8 nm and Nd₂O₃ particles.

The optical micrograph (FIG. 47b) shows that the gold and neodymium oxide particles form agglomerates of very disperse size, ranging from one micron to several hundred microns. These agglomerates are highly porous and consist of a mixture of gold nanoparticles and neodymium oxide nanoparticles.

The percentage content of gold by weight in the composite was 61%.

1. Process for producing a material comprising a mixture of noble metal nanoparticles and rare-earth oxide nanoparticles, comprising the following successive steps:
a) production of a metal alloy comprising at least one noble metal selected from the group consisting of the elements Ru, Rh, Ir, Ag, Au, Pd, Pt, Ni and Cu and at least one rare earth selected from the group consisting of the elements La, Ce, Pr, Nd, Pm, Sm, Eu, Gd, Tb, Dy, Ho, Er, Tm, Yb, Lu, Y and Sc, said alloy containing a crystalline phase the rare earth content of which is greater than 10 at % and the noble metal content of which is between 25 and 75 at %; and
b) oxidation, in an oxidizing atmosphere, of the metal alloy obtained during step a).

2. Process according to claim 1, wherein the alloy produced during step a) further includes at least one transition metal selected from the group consisting of the elements of column IVB of the Periodic Table of the Elements: Ti, Zr, Hf, from column VB; V, Nb and Ta from column VIB; Cr, Mo and W from column VIIB; Mn, Tc and Re from column IIB; and Zn, Cd and Hg, and the elements Fe, Co and Os.

3. Process according to claim 1, wherein, in the alloy produced during step a), the rare earth is partially replaced with an element of the actinide family, selected from the group consisting of Ac, Th and Pa.

4. Process according to claim 1, wherein step a) is carried out by melting the pure elements.

5. Process according to claim 1, wherein step a) is carried out by powder metallurgy or by thin films heated to a temperature of 200° C. or higher.

6. Process according to claim 1, wherein step a) is carried out by mechanical synthesis from the pure elements or from alloys.

7. Process according to claim 1, wherein, when step a) is carried out at a temperature above 50° C., it is performed in an inert or reducing atmosphere.

8. Process according to claim 1, wherein step b) is carried out at a temperature below 800° C.

9. Process according to claim 1, wherein step b) is carried out at ambient temperature.

10. Process according to claim 1, wherein step b) is performed in air.

11. Process according to claim 1, wherein the process includes, between steps a) and b), a heat treatment step for heating the metal alloy to a temperature between 200° C. and 1000° C. in an inert or reducing atmosphere.

12. Process according to claim 1, wherein the process includes, between steps a) and b) a step of grinding the metal alloy.

13. Process according to claim 1, wherein the process includes, after step b), a step of mechanically or ultrasonically grinding the powder obtained.

14. Process according to claim 1, wherein the process includes, during or after step b), a coalescence heat treatment step intended to adjust the size of the particles obtained.

15. Composite comprising a mixture of nanoparticles of at least one noble metal selected from the group consisting of the elements Ru, Rh, Ir, Ag, Au, Pd, Pt, Ni and Cu, and nanoparticles of at least one rare-earth oxide, said rare earth being selected from the group consisting of La, Ce, Pr, Nd, Pm, Sm, Eu, Gd, Tb, Dy, Ho, Er, Tm, Yb, Lu, Y and Sc, said nanoparticles having a particle size of less than 20 nm, wherein the percentage content by weight of noble metal in said composite is equal to or greater than 20%.

16. Composite according to claim 15, it further comprising nanoparticles of at least one transition metal oxide, said transition metal being selected from the group consisting of the elements of column IVB of the Periodic Table of the Elements: Ti, Zr, Hf, from column VB; V, Nb and Ta from column VIB; Cr, Mo and W from column VIIB; Mn, Tc and Re from column IIB; and Zn, Cd and Hg, and the elements Fe, Co and Os.

17. Composite according to claim 15, further comprising nanoparticles of at least one oxide of an element from the actinide family, said element being selected from the group consisting of Ac, Th and Pa.

18. Use of a composite according to claim 15 for catalysis.

19. Use of a composite according to claim 15 for the manufacture of nonlinear optical instruments.

20. Use of a composite according to claim 15 for the production of nanoscale oxide powders involved in the manufacture of sintered ceramics.
